(19) United States
(12) Patent Application Publication
(10) Pub. No.: US 2025/0087490 A1
(43) Pub. Date: Mar. 13, 2025

(54) DEVICE CHIP MANUFACTURING METHOD

(71) Applicant: DISCO CORPORATION, Tokyo (JP)

(72) Inventor: Taro ARAKAWA, Tokyo (JP)

(21) Appl. No.: 18/820,928

(22) Filed: Aug. 30, 2024

(30) Foreign Application Priority Data
Sep. 7, 2023 (JP) 2023-145435

(51) Int. Cl. H01L 21/268; H01L 21/78

(52) U.S. Cl. CPC H01L 21/268; H01L 21/78

(57) ABSTRACT

A device chip manufacturing method includes: forming shield tunnels each having a fine pore and an amorphous region surrounding the fine pore along the planned division lines, by irradiating the wafer from a back surface side with the laser beam having a wavelength transmissive to the wafer in a condition in which a focal point of the laser beam is positioned inside the wafer; and dividing the wafer along the planned division lines where the shield tunnels are formed, by applying an external force to the wafer. Forming the shield tunnels includes setting a beam spot, on the front surface of the wafer, of a light of the laser beam which has passed through the wafer and has reached the front surface of the wafer, to be equal to or smaller than a width of the planned division line.

### CROSS-REFERENCE TO RELATED APPLICATION(S)

The present application claims priority to and incorporates by reference the entire contents of Japanese Patent Application No. 2023-145435 filed in Japan on Sep. 7, 2023.

### BACKGROUND

The present disclosure relates to a device chip manufacturing method.

In recent years, there is an increasing demand for smaller chips in semiconductor wafers and optical device wafers. Accordingly, straightness is important in a cross section of a device chip.

As a processing method for high straightness in the cross section, there has been a method of irradiating a wafer with a pulsed laser beam having a wavelength transmissive to a wafer in a condition in which a focal point of the laser beam is positioned inside the wafer at a region to be divided, so as to form a shield tunnel having a fine pore and an amorphous region surrounding the fine pore (see, for example, JP 6062287 B2).

However, there is a possibility that a pattern is damaged by a light, which has passed through the wafer and has reached a front surface of the wafer, of the laser beam emitted to form a shield tunnel during the processing, thereby reducing the yield.

### SUMMARY

A device chip manufacturing method according to one aspect of the present disclosure is for dividing a wafer into a plurality of chips along a plurality of planned division lines defined on a front surface of the wafer. The wafer has a plurality of devices formed at regions sectioned by the planned division lines. The device chip manufacturing method includes: forming shield tunnels each having a fine pore and an amorphous region surrounding the fine pore along the planned division lines, by irradiating the wafer from a back surface side with the laser beam having a wavelength transmissive to the wafer in a condition in which a focal point of the laser beam is positioned inside the wafer; and dividing the wafer along the planned division lines where the shield tunnels are formed, by applying an external force to the wafer. Forming the shield tunnels includes setting a beam spot, on the front surface of the wafer, of a light of the laser beam which has passed through the wafer and has reached the front surface of the wafer, to be equal to or smaller than a width of the planned division line.

### BRIEF DESCRIPTION OF THE DRAWINGS

FIG. 1 is a perspective view illustrating an example of a wafer to be processed by a device chip manufacturing method according to an embodiment;

FIG. 2 is a flowchart illustrating a flow of the device chip manufacturing method according to the embodiment;

FIG. 3 is a perspective view illustrating a configuration example of a laser processing device that performs a shield tunnel forming step illustrated in FIG. 2;

FIG. 4 is a schematic configuration diagram of a laser beam irradiation unit of the laser processing device illustrated in FIG. 3;

FIG. 5 is a partial cross-sectional side view illustrating a state in the shield tunnel forming step illustrated in FIG. 2;

FIG. 6 is a partial cross-sectional side view illustrating a state after the state of FIG. 5;

FIG. 7 is a perspective view schematically illustrating a structure of a shield tunnel;

FIG. 8 is a perspective view illustrating an example of a beam spot of the light having passed through the wafer;

FIG. 9 is a perspective view illustrating an example of a beam spot of the light having passed through the wafer;

FIG. 10 is a perspective view illustrating a beam spot of a light having passed through a wafer in a comparative example;

FIG. 11 is a partial cross-sectional side view illustrating a state in a wafer dividing step illustrated in FIG. 2; and

FIG. 12 is a partial cross-sectional side view illustrating a state after the state of FIG. 11.

### DETAILED DESCRIPTION

Embodiments according to the present disclosure will be described in detail with reference to the drawings. The present invention is not limited by the contents described in the following embodiments. In addition, the constituent elements described below include those that can be easily conceived by those skilled in the art and those that are substantially the same. Furthermore, the configurations described below can be appropriately combined. In addition, various omissions, substitutions, or changes of the configuration can be made without departing from the gist of the present invention.

### Embodiment

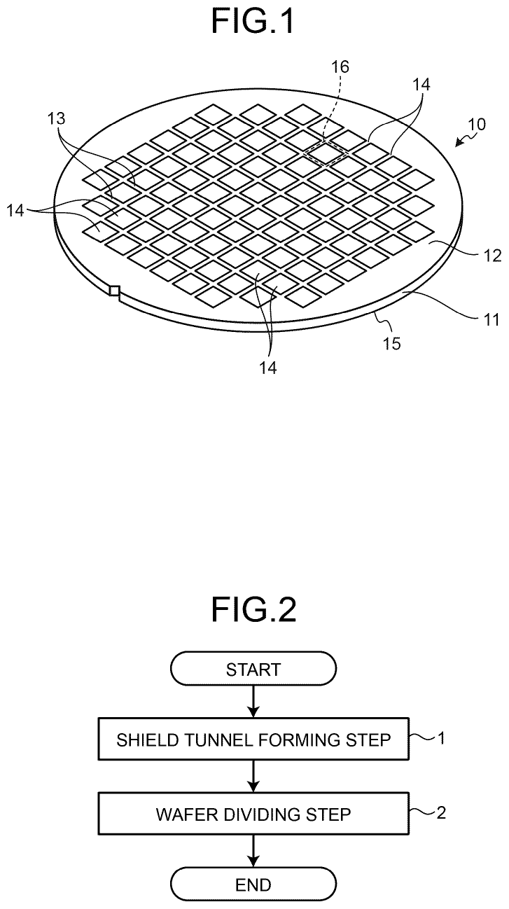

A method for manufacturing a device chip 16 according to an embodiment will be described with reference to the drawings. FIG. 1 is a perspective view illustrating an example of a wafer 10 to be processed by a method for manufacturing the device chip 16 according to an embodiment. The wafer 10 illustrated in FIG. 1 is a disk-shaped wafer, such as a semiconductor device wafer or an optical device wafer, having a substrate 11 made of silicon (Si), sapphire (Al₂O₃), gallium arsenide (GaAs), silicon carbide (SiC), lithium tantalate (LiTaO₃), or the like.

The wafer 10 has, on a front surface 12 thereof, a plurality of planned division lines 13 set in a lattice shape and devices 14 formed in regions sectioned by the planned division lines 13 that intersect one another. The device 14 is, for example, an integrated circuit such as an integrated circuit (IC) or a large scale integration (LSI), or an image sensor such as a charge coupled device (CCD) or a complementary metal oxide semiconductor (CMOS).

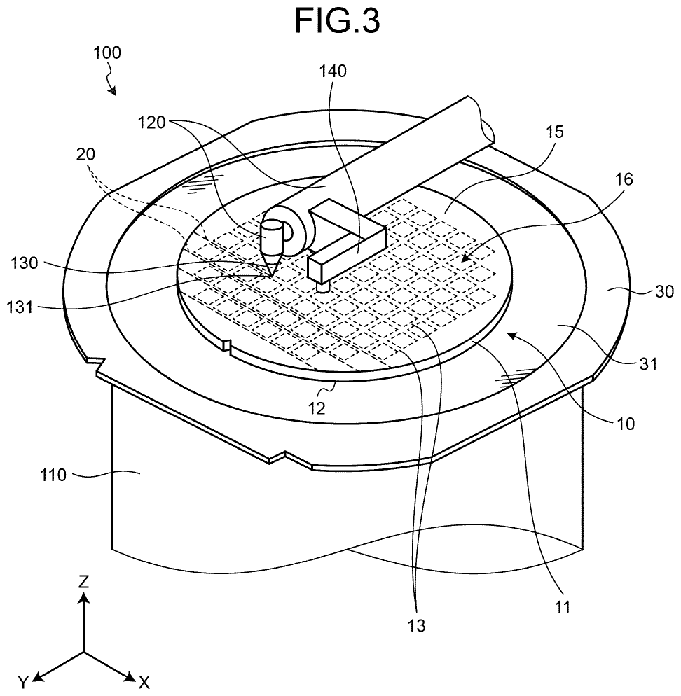

The wafer 10 is conveyed and processed while being supported by, for example, an annular frame 30 and a tape 31 illustrated in FIG. 3, etc. to be described below. The frame 30 is an annular plate member made of a metal or a resin and having an opening larger than an outer diameter of the wafer 10. The tape 31 in the form of a sheet having an outer diameter larger than the opening of the frame 30, and is bonded to a back surface of the frame 30 so as to cover the opening of the frame 30.

The tape 31 may include for example, a substrate layer made of an expandable synthetic resin and an adhesive layer stacked on the substrate layer and made of an expandable and adhesive synthetic resin. Alternatively, the tape 31 may be made of a thermoplastic resin without having an adhesive layer. The wafer 10 is positioned at a predetermined position in the opening of the frame 30, and is fixed to the frame 30 and the tape 31 by bonding a front surface 12 or a back surface 15 (the front surface 12 in the embodiment) to the tape 31.

The wafer 10 is divided into individual devices 14 along the planned division lines 13, so that the device chips 16 are manufactured. The device chip 16 has a square shape in the embodiment, but may have a rectangular shape. The wafer 10 has a disk shape in the embodiment, but may not have a disk shape in the present invention.

FIG. 2 is a flowchart illustrating a flow of the method for manufacturing the device chip 16 according to the embodiment. The method for manufacturing the device chip 16 is a method for manufacturing a plurality of device chips 16 from the wafer 10 to be processed. As illustrated in FIG. 2, the method for manufacturing the device chip 16 includes a shield tunnel forming step 1 and a wafer dividing step 2.

### Laser Processing Device 100

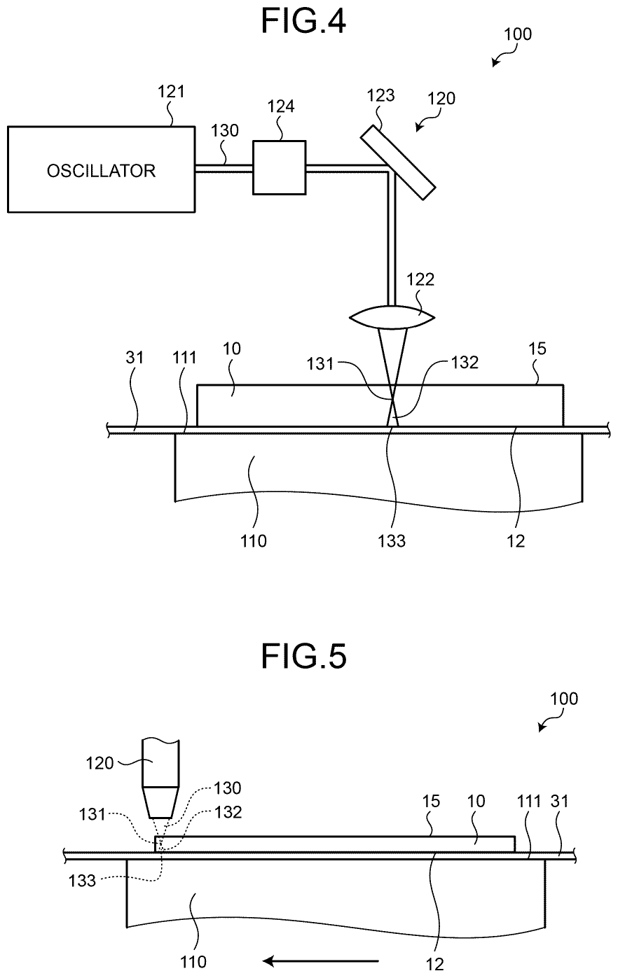

First, a configuration example of a laser processing device 100 that performs the shield tunnel forming step 1 will be described. FIG. 3 is a perspective view illustrating a configuration example of the laser processing device 100 that performs the shield tunnel forming step 1 illustrated in FIG. 2. FIG. 4 is a schematic configuration diagram of a laser beam irradiation unit 120 of the laser processing device 100 illustrated in FIG. 3.

The laser processing device 100 includes a chuck table 110, a laser beam irradiation unit 120, an imaging unit 140, and a moving unit (not illustrated) that relatively moves the chuck table 110 and the laser beam irradiation unit 120. In the following description, the X-axis direction is one direction on a horizontal plane, and is a feeding direction. The Y-axis direction is a direction orthogonal to the X-axis on the horizontal plane, and is an indexing-forward direction. The Z-axis direction is a direction orthogonal to the X-axis direction and the Y-axis direction, and is a focal position adjustment direction.

The chuck table 110 is a support table that holds the wafer 10 on a holding surface 111. For example, the chuck table 110 holds the front surface 12 of the wafer 10 via the tape 31, so that the back surface 15 is exposed. The holding surface 111 has a disk shape and formed of porous ceramic or the like, and is a flat surface parallel to the horizontal direction in the embodiment. The holding surface 111 is connected to a vacuum suction source, for example, via a vacuum suction path, and holds the wafer 10 placed on the holding surface 111 in a sucked manner.

The laser beam irradiation unit 120 is a unit that irradiates the wafer 10 held on the chuck table 110 with a pulsed laser beam 130. As illustrated in FIG. 4, the laser beam irradiation unit 120 includes an oscillator 121, a condenser 122, a mirror 123, and a beam shaping unit 124.

The oscillator 121 oscillates the laser beam 130 having a predetermined wavelength for processing the wafer 10. The condenser 122 is a condensing lens, which condenses the laser beam 130 emitted from the oscillator 121 and emits the condensed laser beam 130 toward the wafer 10 held on the holding surface 111 of the chuck table 110. The mirror 123 is provided on an optical path of the laser beam 130 between the oscillator 121 and the condenser 122 to reflect the laser beam 130 emitted from the oscillator 121 to be guided to the condenser 122.

The beam shaping unit 124 is provided on the optical path of the laser beam 130 between the oscillator 121 and the condenser 122 to shape the beam shape of the laser beam 130 emitted from the oscillator 121 into a predetermined shape. The beam shaping unit 124 includes, for example, a well-known slit mask, a diffractive optical element (DOE), or a spatial light modulator (a liquid crystal on silicon (LCOS)). The slit mask has a plate-shaped base capable of blocking the laser beam 130 and a hole formed in the base. The diffractive optical element adjusts the shape of the laser beam 130 using a light diffraction phenomenon. The spatial light modulator includes a display unit that displays a phase pattern for adjusting optical characteristics when transmitting or reflecting (transmitting in the arrangement illustrated in FIG. 4) the incident laser beam 130, so as to adjust the shape of the emitted laser beam 130.

The imaging unit 140 illustrated in FIG. 3 images the wafer 10 held on the chuck table 110. The imaging unit 140 includes a CCD camera or an infrared camera. For example, the imaging unit 140 is fixed to be adjacent to the condenser 122 (see FIG. 4) of the laser beam irradiation unit 120. The imaging unit 140 images the wafer 10 to obtain an image used for performing an alignment of the wafer 10 and the laser beam irradiation unit 120, and outputs the obtained image.

### Shield Tunnel Forming Step 1

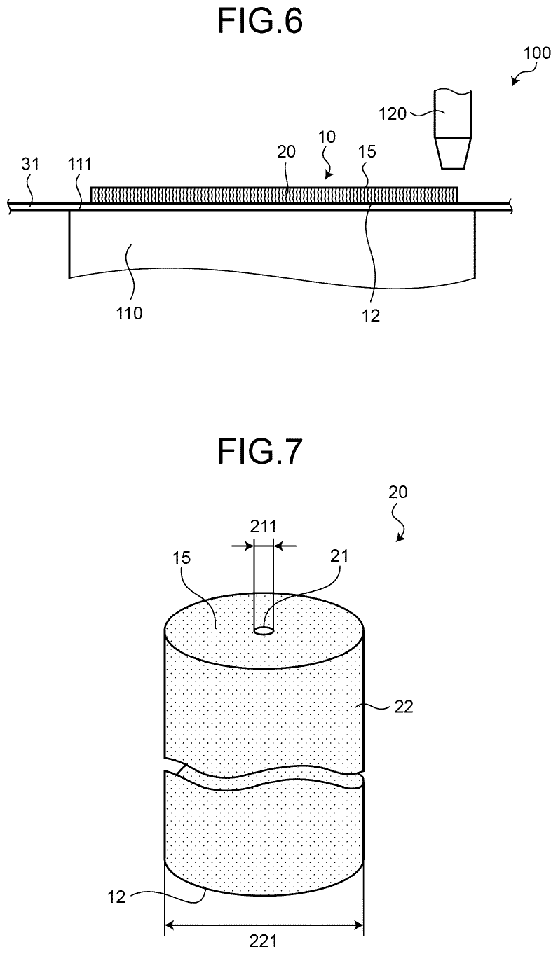

FIG. 5 is a partial cross-sectional side view illustrating a state in the shield tunnel forming step 1 illustrated in FIG. 2. FIG. 6 is a partial cross-sectional side view illustrating a state after the state of FIG. 5 FIG. 7 is a perspective view schematically illustrating a structure of a shield tunnel 20. The shield tunnel forming step 1 is a step of forming shield tunnels 20 each having a fine pore 21 and an amorphous region 22 surrounding the pore 21 along the planned division lines 13, by irradiating the wafer 10 from the back surface 15 side with the laser beam 130 having a wavelength transmissive to the wafer 10 in a condition in which the focal point of the laser beam is positioned inside the wafer 10.

In the shield tunnel forming step 1, first, the front surface 12 of the wafer 10 is held in a sucked manner on the holding surface 111 of the chuck table 110 via the tape 31. Next, the condenser 122 (see FIG. 4) of the laser beam irradiation unit 120 is aligned with the planned division line 13 of the wafer 10. Specifically, the moving unit (not illustrated) moves the chuck table 110 to a processing region below the laser beam irradiation unit 120.

Next, the imaging unit 140 (see FIG. 3) images the wafer 10, so that the planned division line 13 is detected. When the planned division line 13 is detected, an alignment is performed to align an irradiation unit of the laser beam irradiation unit 120 with the planned division line 13 of the wafer 10. After the irradiation unit of the laser beam irradiation unit 120 is aligned to face the back surface 15 of the wafer 10 corresponding to a region where the planned division line 13 is set in the vertical direction, a focal point 131 of the laser beam 130 is set inside the wafer 10.

In the shield tunnel forming step 1, next, the pulsed laser beam 130 is emitted into the wafer 10, while the chuck table 110 and the laser beam irradiation unit 120 are relatively moved in the feeding direction so that the laser beam 130 is emitted along the planned division line 13. As a result, the shield tunnels 20 each extending from the vicinity of the focal point 131 of the laser beam 130 positioned inside the wafer 10 toward both the front surface 12 and the back surface 15 of the wafer 10 are formed along the planned division line 13 as illustrated in FIG. 6. The shield tunnels 20 are formed at predetermined intervals along the planned division line 13 owing to the irradiation of the pulsed laser beam 130.

As illustrated in FIG. 7, the shield tunnel 20 has the fine pore 21 extending from the front surface 12 to the back surface 15 of the wafer 10, and a cylindrical amorphous region 22 surrounding the fine pore 21. The fine pore 21 has an inner diameter 211 of about 1 μm, the amorphous region 22 has an outer diameter 221 of about 5 μm, and an interval between the adjacent amorphous regions 22 is about 10 μm.

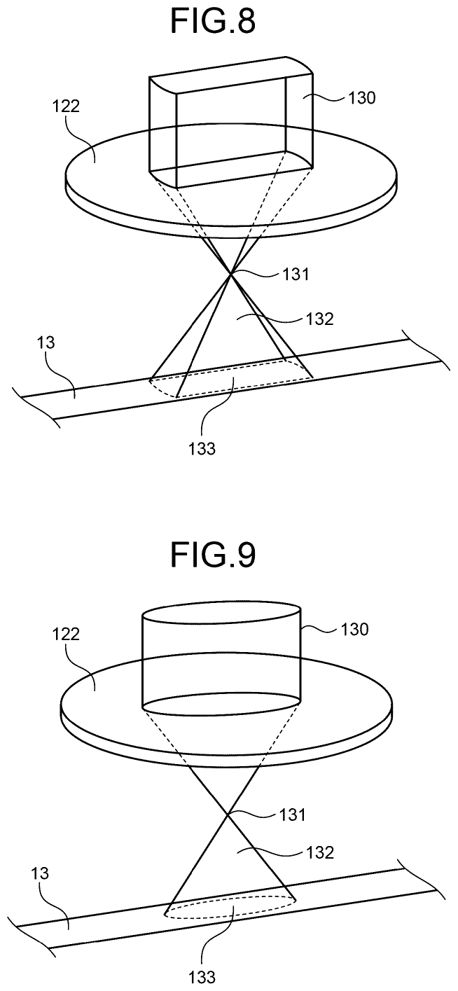

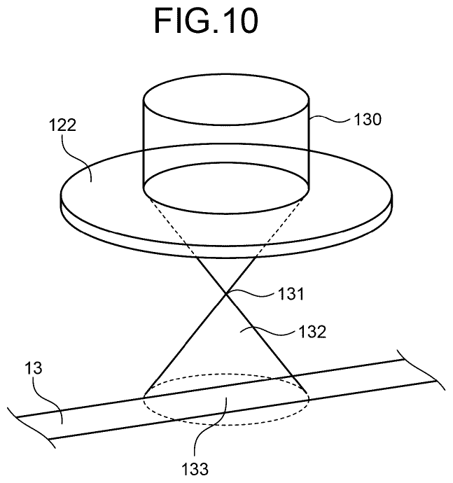

In this case, a beam spot 133 on the front surface 12 of light 132 of the laser beam 130, which has passed through the wafer 10 and has reached the front surface 12 of the wafer 10, is set to be equal to or smaller than the width of the planned division line 13. FIGS. 8 and 9 are perspective views each illustrating an example of the beam spot 133 of the light 132 having passed through the wafer 10. FIG. 10 is a perspective view illustrating a beam spot 133 of the light 132 having passed through the wafer 10 in a comparative example. In each of FIGS. 8 to 10, the wafer 10 is not entirely illustrated, and only the planned division line 13 formed on the front surface 12 is illustrated. In each of FIGS. 8 to 10, it is assumed that the focal point 131 is positioned inside the wafer 10.

For example, as illustrated in FIG. 8, the beam spot 133 may be set to have a rectangular shape having a longitudinal direction parallel to a direction in which the planned division line 13 extends. Alternatively, for example, as illustrated in FIG. 9, the beam spot 133 may be set to have an elliptical shape having a major axis along a direction parallel to the direction in which the planned division line 13 extends. In other words, in the laser processing device 100 that performs the shield tunnel forming step 1, the beam shape of the laser beam 130 emitted from the oscillator 121 is adjusted by the beam shaping unit 124 so that the beam spot 133 has a desired shape. In the present specification, the “rectangular shape” is not limited to a strict rectangular shape, and includes a shape with rounded corners. Furthermore, in the present specification, the “elliptical shape” is not limited to a strict elliptical shape, and may be any shape as long as it is a shape defined by a generally closed curve protruding on both sides, and may be, for example, an oval shape.

As the comparative example, FIG. 10 illustrates a beam spot 133 in a case where the beam shape of the laser beam 130 is not adjusted by the beam shaping unit 124. In such a case, due to the beam spot 133 exceeding the width of the planned division line 13, the light 132 having reached the front surface 12 of the wafer 10 or having passed through the wafer 10 is emitted to a region where the device 14 is formed. In the embodiment, as illustrated in FIG. 8 or 9, by setting the beam spot 133 to be equal to or smaller than the width of the planned division line 13, the emission of the light 132 having passed through the wafer 10 to the device 14 is suppressed.

The processing conditions in the embodiment are as follows. The defocus is a device setting distance from the back surface 15 of the wafer 10 to the focal point 131. In the embodiment, the beam diameter before focus is a diameter of the laser beam 130 before entering the beam shaping unit 124 after being emitted from the oscillator 121. In addition, the beam shape after focus is a shape of the beam spot 133 on the front surface 12 of the light 132 of the laser beam 130 having passed through the wafer 10.
Wavelength: 1064 nm
Output: 1.6 W
Defocus: 0.015 mm
Frequency: 40 KHz
Feed speed: 700 mm/s
Beam diameter before focus: 3.0 mm
Beam shape after focus: rectangular shape of 60 μm×20 μm

### Wafer Dividing Step 2

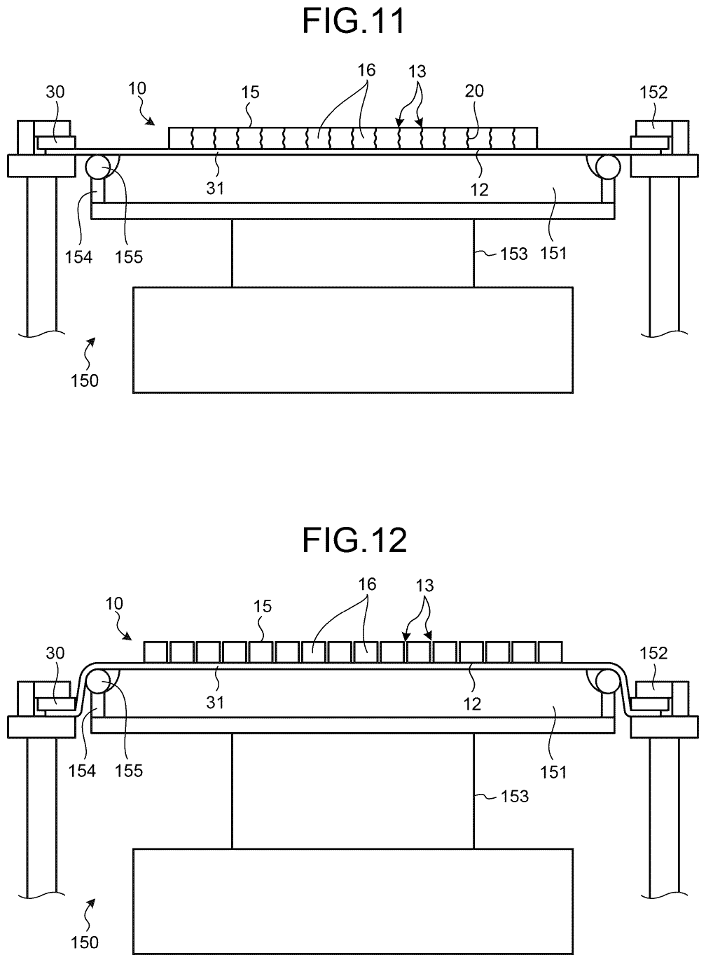

FIG. 11 is a partial cross-sectional side view illustrating a state in the wafer dividing step 2 illustrated in FIG. 2. FIG. 12 is a partial cross-sectional side view illustrating a state after the state of FIG. 11. The wafer dividing step 2 is a step of dividing the wafer 10 along the planned division lines 13 where the shield tunnels 20 are formed by applying an external force to the wafer 10.

As illustrated in FIGS. 11 and 12, in the wafer dividing step 2 according to the embodiment, an expansion device 150 applies an external force to the tape 31 in the radial direction to divide the wafer 10. The expansion device 150 includes a chuck table 151, a clamping member 152, a lifting unit 153, a push-up member 154, and roll members 155. The push-up member 154 has a cylindrical shape, provided coaxially on the outer periphery of the chuck table 151. The roll members 155 are rotatably provided on the same plane as or slightly above the holding surface of the chuck table 151 and at an upper end of the push-up member 154.

First, as illustrated in FIG. 11, in the wafer dividing step 2, the front surface 12 of the wafer 10 is positioned on the holding surface (upper surface) of the chuck table 151 via the tape 31, and the outer peripheral portion of the frame 30 is fixed by the clamping member 152. In this state, the roll member 155 are in contact with the tape 31 between an inner edge of the frame 30 and an outer edge of the wafer 10.

Next, as illustrated in FIG. 12, in the wafer dividing step 2, the chuck table 151 and the push-up member 154 are integrally lifted by the lifting unit 153. At this time, since the outer peripheral portion of the tape 31 is fixed by the clamping member 152 via the frame 30, a portion between the inner edge of the frame 30 and the outer edge of the wafer 10 is expanded in the plane direction. Furthermore, the roll members 155 provided at the upper end of the push-up member 154 reduces friction with the tape 31.

In the wafer dividing step 2, as a result of the expansion of the tape 31, a radial tensile force acts on the tape 31. When the radial tensile force acts on the tape 31, the wafer 10 onto which the tape 31 is bonded is divided into the individual device chips 16 with the shield tunnels 20 formed along the planned division line 13 as break starting points, as illustrated in FIG. 12. After the wafer 10 is divided into the device chips 16, the device chips 16 are picked up from the tape 31 by a well-known picker, for example, in a pickup process.

In the wafer dividing step 2, the method of applying the external force to the wafer 10 is not limited to the method of applying the external force by expanding the tape 31 illustrated in FIGS. 11 and 12. For example, a braking device may apply a pressing force in the thickness direction of the wafer 10 along the planned division line 13.

As described above, in the method for manufacturing the device chip 16 according to the embodiment, the beam spot 133, on the front surface 12 of the wafer 10, of the light 132 which has passed through the wafer 10 and has reached the front surface 12 of the wafer 10, of the laser beam 130 emitted for forming the shield tunnel 20, is set to be equal to or smaller than the width of the planned division line 13. As a result, the light 132 having passed through the wafer 10 is prevented from exceeding the width of the planned division line 13 and prevented from being emitted to a region where the devices 14 are formed. This provides advantageous in that damage to the pattern formed on the front surface 12 of the wafer 10 can be suppressed, thereby improving the yield.

According to the present disclosure, it is possible to suppress damage to a pattern formed on a front surface of a wafer when the wafer is divided along a planned division line.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A device chip manufacturing method for dividing a wafer into a plurality of chips along a plurality of planned division lines defined on a front surface of the wafer, the wafer having a plurality of devices formed at regions sectioned by the planned division lines,
the device chip manufacturing method comprising:
forming shield tunnels each having a fine pore and an amorphous region surrounding the fine pore along the planned division lines, by irradiating the wafer from a back surface side with the laser beam having a wavelength transmissive to the wafer in a condition in which a focal point of the laser beam is positioned inside the wafer; and
dividing the wafer along the planned division lines where the shield tunnels are formed, by applying an external force to the wafer, wherein
forming the shield tunnels includes setting a beam spot, on the front surface of the wafer, of a light of the laser beam which has passed through the wafer and has reached the front surface of the wafer, to be equal to or smaller than a width of the planned division line.

2. The device chip manufacturing method according to claim 1, wherein
forming the shield tunnels includes setting the beam spot, on the front surface of the wafer, of the light of the laser beam which has passed through the wafer and has reached the front surface of the wafer, to have a rectangular shape having a longitudinal direction parallel to a direction in which the planned division line extends.

3. The device chip manufacturing method according to claim 1, wherein
forming the shield tunnels includes setting the beam spot, on the front surface of the wafer, of the light of the laser beam which has passed through the wafer and has reached the front surface of the wafer, to have an elliptical shape with a major axis along a direction parallel to a direction in which the planned division line extends.
